(19) United States
(12) Patent Application Publication
(10) Pub. No.: US 2016/0247665 A1
(43) Pub. Date: Aug. 25, 2016

(54) PROCESS AND SYSTEM FOR THE SUBMICRON STRUCTURING OF A SUBSTRATE SURFACE

(71) Applicant: CENTRE NATIONAL DE LA RECHERCHE SCIENTIFIQUE, Paris (FR)

(72) Inventors: Thierry Belmonte, Neuves-Maisons (FR); Thiago Silva Amaral, Jardim das Americas Parana (BR); Thomas Gries, Liverdun (FR); Cedric Noel, Nancy (FR); Rodrigo Perito Cardoso, Vista Alegre Curibita Parana (BR)

(21) Appl. No.: 15/027,331

(22) PCT Filed: Sep. 23, 2014
(86) PCT No.: PCT/FR2014/052357

§ 371 Date: Apr. 5, 2016

(30) Foreign Application Priority Data
Oct. 7, 2013 (FR) 1359713

(51) Int. Cl. H01J 37/32; B81C 1/00

(52) U.S. Cl. CPC H01J 37/3244; B81C 1/00373; B81C 1/00531; H01J 37/32009; H01J 2237/334

(57) ABSTRACT

The subject of the invention is a process for submicron structuring of a surface (6) of a substrate (3) comprising the steps of generating a plasma at atmospheric pressure above said surface (6); and of injecting onto said surface (3), through said plasma, at least one gaseous precursor by means of at least one capillary (5) of submicron diameter.

The process may be carried out in a 3D printing system comprising a plate (2) that is mobile in three directions.

The present invention relates generally to the structuring of a surface of a substrate, in particular with a view to producing two-dimensional objects (2D objects) or three-dimensional objects (3D objects).

Structuring is understood to mean the addition or removal of materials.

The fields of application more specifically targeted by the invention are all the sectors in which it is sought to obtain high spatial resolutions of patterns produced on the surfaces (production of OLED screens, microengineering and MEMS, lab-on-a-chip microreactors, electronics, etc.).

Processes are already known that make it possible to manufacture 3D objects on the submicron scale. The document entitled “Construction d' objets à léchelle submicronique” [Construction of objects on the submicron scale](Hervé Dallaporta, Frédéric Bedu, accessible with the link http://liris.cnrs.fr/˜cnriutO8/actes/articles/112.pdf) describes in particular a method of constructing objects on submicron scales by decomposition of precursors assisted by a focused ion beam. In order to obtain the deposition of a material on a surface, a precursor containing the chemical elements constituting the material is conveyed by a gaseous pathway. Each point of the construction is then exposed to focused ions in order to obtain the most localized possible decomposition of the precursor. In this method, the resolution obtained is a function of the fineness of the beam of ions that can be generated. Although this technique has been demonstrated, the implementation thereof remains complex and very expensive due to the fact that the beam of ions must be generated under vacuum.

The field of three-dimensional (3D) manufacturing is currently booming. First developed for rapid prototyping, this additive manufacturing technique is increasingly used by manufacturers for large-scale production, or even by individuals for producing customized objects.

Additive manufacturing consists in stacking layers one by one so as to construct a complete object from the numerical data of a 3D file model. In other words, the object that it is desired to obtain is first modelled in three dimensions, for example using a CAD tool. The 3D file obtained is then sent to a specific piece of equipment that processes the 3D file so as to slice the virtual 3D object along a given orientation into parallel sections of determined thickness. The known pieces of equipment that are used differ in particular as a function of:
the base materials used, the latter generally being in liquid, powder, wire or ribbon form;
the energy used for the forming, this energy generally originating from a laser source, a source of visible, infrared or ultraviolet light, or else from a heat source; and
the physical forming procedure (for example melting then solidification, sintering) or chemical forming procedure (polymerization or crosslinking) used.

Thus, and by way of examples, the techniques of selective laser melting (SLM) and of selective laser sintering (SLS) combine a laser beam with a metal or plastic powder in order to melt or sinter the powder.

The binder jetting technique, greatly inspired by 2D inkjet printers, consists in impregnating a layer of ceramic, plastic or metallic powder with a binder by means of a binder jetting nozzle that can be moved along two axes. The solidification process may be accelerated by the use of ultraviolet lighting.

The multijet modelling technique consists in depositing a layer of liquid resin.

Other techniques, such as fused deposition modelling (FDM) use a heated nozzle controlled according to an algorithm for extruding a filament that is deposited at a temperature slightly below the melting point of the material of the filament and solidifies virtually instantaneously on coming into contact with the preceding layer.

All these three-dimensional printing techniques have the enormous advantage of being much less expensive to implement, due to the fact in particular that they do not require complex equipment with vacuum chambers.

Nevertheless, the results in terms of spatial resolution still remain too limited to envisage applying them to the domains targeted by the present invention. Indeed, in the best case scenarios, it is possible to expect to obtain resolutions of the order of a few tens of micrometres, whereas the targeted domains require resolutions of the order of around a hundred nanometres.

Furthermore, processes for producing thin films are known, especially in the semiconductor industry, which use jets of microplasmas at atmospheric pressure in order to react one or more gaseous precursors to which a substrate is exposed. Documents KR20120005870A and JP2006274290A describe in particular processes in which the precursor and the plasma are mixed in the same capillary tube. In techniques of this type, the deposition zone corresponds however to the size of the plasma, which is itself limited by the Debye length. Yet, today, it is not known how to create a plasma at atmospheric pressure having a size that is less than 30 microns.

The objective of the invention is to overcome the drawbacks of the various aforementioned techniques by proposing a process and a system for the structuring of a surface of a substrate that makes it possible, at lower cost, to obtain submicron spatial resolutions.

In order to do this, one subject of the present invention is a process for submicron structuring of a surface of a substrate comprising the following steps:

generation of a plasma at atmospheric pressure above said surface;

injection onto said surface, through said plasma, of at least one gaseous precursor by means of at least one capillary of submicron diameter.

With this process, deposition or etching sizes are obtained that are no longer dependent on the size of the plasma used and which may be reduced to the submicron diameter of the capillary used for injecting the gaseous precursor.

According to other possible features of the process:
the gaseous precursor and the plasma are selected in order to produce either a localized etching, or a localized deposition;
several gaseous precursors may be used successively by means of the same capillary, or successively by means of a plurality of capillaries of submicron diameters, or simultaneously into a plurality of capillaries of submicron diameters;
the plasma generated at atmospheric pressure is preferably a cold plasma;
the capillary advantageously has a diameter of the order of 100 nanometres;
the process may additionally comprise a step of localized heating of the substrate, in order to increase the kinetics of the chemical reaction of the gaseous precursor and of the plasma.

Another subject of the invention is a system for the submicron structuring of a surface of a substrate, said system comprising:

at least one plasma source capable of generating a plasma at atmospheric pressure above said surface;

at least one capillary of submicron diameter for the injection onto said surface of at least one gaseous precursor through said plasma.

In accordance with possible embodiments:
the system may additionally comprise means capable of allowing a relative movement between, on the one hand, the substrate and, on the other hand, the assembly formed by said at least one capillary and said at least one plasma source, for example a plate that is mobile in at least two orthogonal directions, parallel to said surface;
the plate may additionally also be mobile in a direction orthogonal to said surface;
a control means capable of ensuring a minimum safety distance between the end of the capillary and said surface is advantageously provided in order to avoid damaging the capillary.

The invention will be better understood in view of the following detailed description, given with reference to the appended figures, in which:

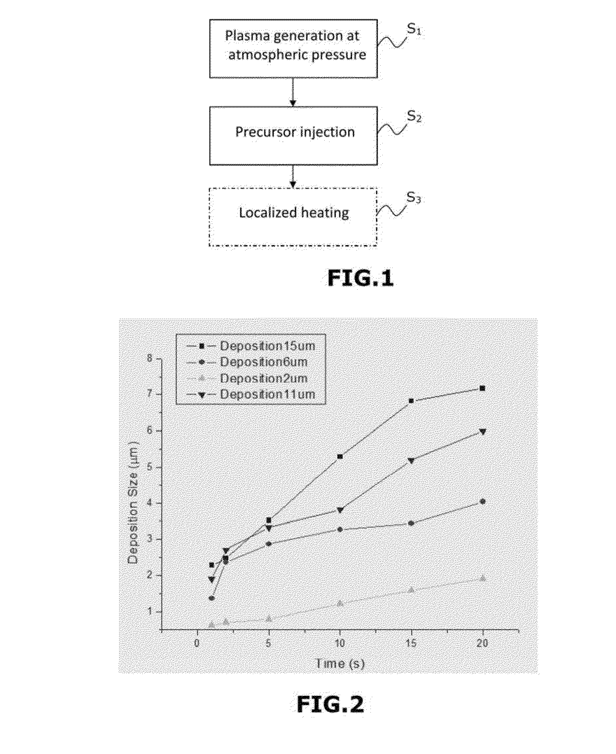

FIG. 1 represents steps in accordance with the structuring process according to the invention;

FIG. 2 is an example of experimental curves obtained with various capillary diameters;

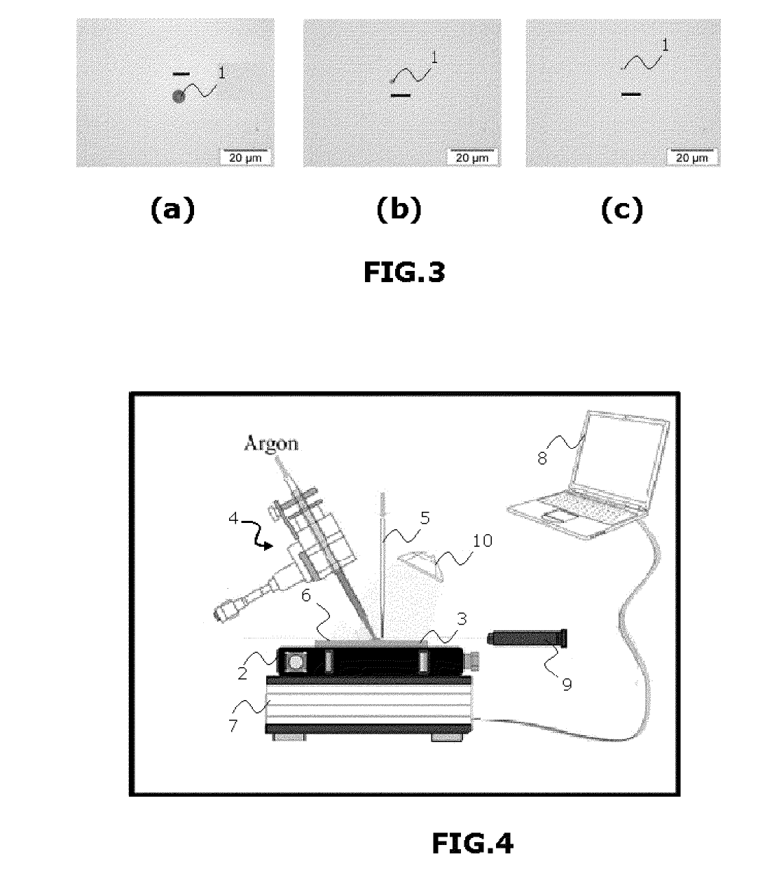

FIGS. 3 (a) to (c) represent, as top views, examples of depositions obtained on a substrate surface;

FIG. 4 schematically illustrates an experimental system for the implementation of the process from FIG. 1, for a three-dimensional printing application.

The present invention is part of the general idea of using the principle of an inkjet printer, replacing the ink with a precursor gas, which is easier to handle than a liquid, and using, for the forming, a plasma generated under atmospheric pressure.

As was indicated above, the techniques used until now combining a precursor gas mixed with a plasma have not made it possible to produce depositions having a size of less than around 30 microns, which corresponds to the size of the plasma generated.

The present invention proposes to completely separate the injection of the precursor gas from that of the plasma. The tests carried out by the Applicant have indeed shown that it is possible to obtain, on the surface of a substrate, a deposition of material, the size of which corresponds substantially to the diameter of a jet of precursor gas directed towards the surface and passing through a volume of plasma generated at atmospheric pressure in the vicinity of the surface. It is therefore possible to convey a precursor gas in a very localized manner to the surface of a substrate owing to the use of a capillary of very small diameter, such as those used in medicine, especially for handling ova. These capillaries are glass tubes which have been drawn and the tips of which are formed in order to achieve very small dimensions, typically varying from 100 nanometres to a few microns.

FIG. 1 depicts the steps of a process in accordance with the invention for obtaining a structured zone on the surface of a substrate. Firstly a plasma is generated at atmospheric pressure above the substrate, in the vicinity of the surface of the substrate (step S₁), then a gaseous precursor is injected, preferably at high pressure, by means of a capillary of submicron diameter (step S₂). The jet of gas is directed onto the surface and passes through the plasma. The reaction of the precursor with the gas of the plasma makes it possible to produce isolated structurings of submicron size. The pressure used for injecting the precursor gas depends on the diameter of the capillary and on the nature of the precursor gas. It is possible to work typically at pressures located between 1 and 100 bar.

FIG. 2 illustrates, by way of examples, the change in the carbon deposition sizes obtained over time for tests carried out with four capillaries of different diameters (2 microns, 6 microns, 11 microns and 15 microns) used for injecting acetylene through an argon plasma generated at atmospheric pressure. The minimum size achieved is 700 nm, which is around 40 times smaller than the minimum size of commercial 3D printers. FIGS. 3 (a), (b) and (c) illustrate, as top views, three examples of spots 1 of various sizes obtained.

The nature of the structuring depends on the choice of the precursor gas and the plasma. Certain combinations will make it possible to obtain a deposition whereas others will generate an etching. In addition, depending on the choice of the precursor gases, it is possible to obtain depositions of varied nature, such as metals, ceramics and plasma polymers.

The plasma used may preferably be a cold plasma. It must be generated at atmospheric pressure. It may be of any size greater than the diameter of the capillary. It may be excited continuously or at various frequencies, may or may not be pulsed, may enable a heat gain that acts as simultaneous heating of the surface such as for example microwave plasmas or may operate at ambient temperature in order to deposit labile materials, such as for example pulsed plasmas. In certain cases, a step S₃ of localized heating of the substrate may be provided for the purpose of accelerating the chemical reaction of the gaseous precursor and of the plasma.

Depending on the 2D or 3D object that it is desired to produce, provision may be made to use several capillaries of identical or different submicron diameters that make it possible to simultaneously inject a same gaseous precursor or several gaseous precursors through the same plasma. As a variant, a same capillary may optionally be used to successively inject several precursor gases.

FIG. 4 schematically illustrates a system that implements the process for the production of a 3D object with submicron resolutions:

The system comprises a plate 2 intended to receive a substrate 3, a device 4 for generating a cold plasma, and a capillary 5 positioned above the surface 6 of the substrate 3. The plate 2 is preferably laid on an anti-vibration table 7 to which the device 4 and the capillary 5 are fastened. The plate 2 is mobile along at least two orthogonal directions in a plane parallel to the surface 6, and a third direction orthogonal to the other two directions. The displacement of the plate 2 is controlled by software means 8 (represented here in the form of a computer) as a function of the virtual 3D object that it is desired to produce. Positioning optics 9 make it possible to guarantee the existence of a safety distance between the surface 6 of the substrate and the tip of the capillary 5 during the vertical displacement of the plate 2, in order to protect the capillary 5. A heating means 10 may be provided in order to increase the kinetics of the reaction between the gaseous precursor and the plasma. The rate of displacement of the plate 2 is calculated as a function of various parameters, in particular the rate of deposition or etching. If various precursors are used successively, a purge means (not represented) is advantageously provided in order to clean the capillary between two injections. In other systems, provision may of course be made to have several capillaries fastened on top of the table.

Owing to the process according to the invention, it is possible to produce substrate surface structurings having very high resolutions, especially 2D or 3D printings and/or etchings, with relatively inexpensive equipment. To date, the resolutions capable of being obtained are limited only by the diameter of the capillaries used (today of the order of 100 nanometres) and could therefore be further improved as a function of the development of the techniques for manufacturing capillaries with even smaller diameters.

1. Process for submicron structuring of a surface of a substrate comprising the following steps:
generation of a plasma at atmospheric pressure above said surface;
injection onto said surface, through said plasma, of at least one gaseous precursor by means of at least one capillary of submicron diameter.

2. Process according to claim 1, that wherein the gaseous precursor and the plasma are selected in order to produce a localized etching.

3. Process according to claim 1, wherein the gaseous precursor and the plasma are selected in order to produce a localized deposition.

4. Process according to claim 3, wherein several gaseous precursors are injected successively into said at least one capillary, or successively into a plurality of capillaries of submicron diameters, or simultaneously into a plurality of capillaries of submicron diameters.

5. Process according to claim 1, wherein the plasma generated at atmospheric pressure is a cold plasma.

6. Process according to claim 1, wherein the capillary has a diameter of the order of 100 nanometres.

7. Process according to claim 1, wherein said process additionally comprises a step of localized heating of the substrate.

8. System for the submicron structuring of a surface of a substrate, said system comprising:
at least one plasma source capable of generating a plasma at atmospheric pressure above said surface;
at least one capillary of submicron diameter for the injection onto said surface of at least one gaseous precursor through said plasma.

9. System according to claim 8, wherein said system additionally comprises means capable of allowing a relative movement between, on the one hand, the substrate and, on the other hand, the assembly formed by said at least one capillary and said at least one plasma source.

10. System according to claim 8, wherein said means comprise a plate that is mobile in at least two orthogonal directions parallel to said surface.

11. System according to claim 10, wherein said plate is additionally mobile in a direction orthogonal to said surface.

12. System according to claim 11, wherein said system additionally comprises a control means capable of ensuring a minimum safety distance between the end of the capillary and said surface.
